(19) United States
(12) Patent Application Publication
(10) Pub. No.: US 2014/0346022 A1
(43) Pub. Date: Nov. 27, 2014

(54) OPERATING ELEMENT

(71) Applicant: E.G.O. Elektro-Geraetebau GmbH, Oberderdingen (DE)

(72) Inventors: Hartmut KELLER, Weingarten (DE); Dennis SCHMID, Kraichtal (DE); Frank GRAFF, Radensieben (DE); Uwe UNGETHUEM, Spreenhagen (DE)

(73) Assignee: E.G.O. Elektro-Geraetebau GmbH, Oberderdingen (DE)

(21) Appl. No.: 14/282,701

(22) Filed: May 20, 2014

(30) Foreign Application Priority Data
May 27, 2013 (DE) 10 2013 209 849.9
Feb. 19, 2014 (EP) 14155812.2

(51) Int. Cl. H03K 17/96

(52) U.S. Cl. CPC H03K 17/962
USPC 200/345

(57) ABSTRACT

An operating element has an operating element housing, on the upper side of which a protruding rib made of elastic material is arranged, the rib, or its cross section, being formed for geometrical elasticity. This can be achieved by an elastically protruding section having an extent direction outward away from the rest of the rib, essentially obliquely with respect to a plane of the upper side of the operating element.

### CROSS-REFERENCE TO RELATED APPLICATIONS

This application claims priority to European Application No. 14155812.2 filed Feb. 19, 2014, and German Application No. 10 2013 209 849.9 filed May 27, 2013, which are hereby incorporated herein in their entireties by reference.

### TECHNOLOGICAL FIELD

The invention relates to an operating element having an operating element housing, in the upper region, or on the upper side, of which at least one rib made of elastic material is arranged.

### BACKGROUND

It is known, for example from WO 2013/174728 A1, to form such an operating element for an operating device according to the functional principle with capacitive touch sensors. On the upper side of an operating element housing, an upwardly protruding rib made of elastic and electrically conductive material is in this case arranged in a circumferential shape. It is placed at the bottom on a printed circuit board as a carrier, and is electrically connected thereto, and it acts as a capacitive touch sensor for a corresponding touch switch of an operating device.

### BRIEF SUMMARY

The object of the invention is to provide an operating element as mentioned in the introduction, with which problems of the prior art can be solved and, in particular, it is possible to make such an operating element usable in a practically suitable and versatile way, as well as functionally reliable.

The object is achieved by an operating element having the features of claim 1. The object is also achieved by an operating element having the features of claim 11. Advantageous and preferred configurations of the invention are the subject matter of the other claims, and will be explained in more detail below. The wording of the claims is incorporated into the content of the description by explicit reference.

In the upper region of the operating element housing, or on its upper side, at least one rib extends along at least partially. This rib consists of elastic material and protrudes from the operating element housing, advantageously upward and particularly advantageously also somewhat beyond it laterally.

According to a first basic aspect of the invention, in the longitudinal extent of the rib, or in the rib itself, an interruption or a gap is provided so that the rib can be subdivided into at least two correspondingly protruding rib sections. The rib therefore does not extend continuously along the entire longitudinal side of the operating element housing. Although the interruption or gap, or the plurality of interruptions or gaps, do not entail a change in the shape, or cross-sectional shape, of the rib, it is nevertheless possible to achieve a reduction in the application force with which the operating element, or a component carrier comprising a multiplicity of such operating elements thereon, has to be pressed onto a lower side of a cover or of an operating panel, because in fact substantially less rib length has to be pressed. This application force can be influenced by the nature or the scope of the interruption of the rib. Lastly, in this aspect of the invention, the required application force is determined by the ratio of the total length of the rib, or of the rib sections, to the total length or sum of the lengths of the interruptions or gaps. Whether they are then respectively subdivided into few long or more shorter rib sections is of somewhat less importance, although this may naturally have a simplifying or complicating effect in terms of production technology.

The operating element housing may generally be formed angularly in plain view, or quadrilaterally, and it is advantageously rectangular. In this case, in principle, ribs, or rib sections, may be provided along each side, the rib being subdivided into at least two, and under certain circumstances even more, rib sections by the interruption or gaps along each side.

On the one hand, it is possible for the sum of the lengths of the interruptions or gaps along a side to be less than the sum of the lengths of the individual rib sections. The total length of the interruptions may for example be from 20% to 60% of the total length of the rib sections, i.e. significantly less. The rib sections extend on a larger percentage of a longitudinal side of the operating element housing.

On the other hand, the sum of the lengths of the interruptions or gaps in the rib may be greater than the sum of the lengths of the rib sections themselves. Advantageously, it may be significantly greater, i.e. for example from 5 times to 20 times as great as the sum of the lengths of the rib sections. Thus, rib sections extend only on a small percentage of a longitudinal side of the operating element housing, for example from 5% to 20%.

Here, in the case of an operating element housing which is polygonal in plan view, and which is advantageously rectangular, it is possible to provide only very short rib sections which, in particular, are approximately as long as they are wide. They thus resemble more an upwardly projecting cylindrical projection than a rib in this extreme embodiment of the invention with very large interruptions and very small rib sections. Short rib sections of this type may in principle be provided at any position on top of the operating element housing, advantageously only one of them per longitudinal side of the operating element housing. Particularly advantageously, these rib sections may be provided only in corner regions of the operating element housing, or precisely one such rib section or small projection in each corner region. In this case, it is to be expected that an application force of the operating element housing from below onto an operating panel or cover is very small and good bearing of the operating element housing with all rib sections or projections on the lower side is possible.

In another configuration of the invention, the rib sections may be about 1 times to 6 times as long as they are wide. They thus tend to be elongate rib sections. It is also possible for the rib sections respectively to have a length along the sides of the operating element housing which is between 50% and 200% of their width. This is then rather the previously described case of very short rib sections or projections.

In general, the width of the ribs may correspond to between 50% and 150% of the height of the ribs. Both are therefore approximately of the same order of magnitude. For the ribs or rib sections, this may relate to the width of the ribs at the base on the operating element housing, or on its upper side.

According to a second basic aspect of the invention, the rib, or a cross section of the rib, which is advantageously the same over substantial length ranges, is formed in such a way that it is not only materially elastic through the selection of a corresponding elastomer, but also geometrically elastic, i.e. it is formed for geometrical elasticity. Thus, in addition to possible limitations due to a material selection in terms of material strength and possibly electrical conductivity and thermal stability, the overall elasticity of the rib can be influenced and, in particular, increased further. For example, even with relatively hard or inelastic materials with a high Shore hardness, for example a hardness of from 50 to 70 or even 80 Shore A, an overall very elastic rib can be achieved, namely precisely by geometrical elasticity of the rib itself, or its cross section.

Advantageously, an elastically or spring-elastically protruding section of the rib may be provided, which extends away from it in a direction essentially oblique with respect to a plane of the upper side of the operating element. Elasticity of the rib is then achieved not only by pure compressability, but by the deformation or bending of the rib, or of the protruding section. Pressing of the operating element, i.e. of the operating element housing, onto a control surface, in particular on the lower side thereof, can then be carried out for reliable and sufficient bearing of the rib or plurality of ribs of the operating element housing with little force. Lower forces are therefore required overall, or, in the case of an operating device comprising a multiplicity of such operating elements or operating element housing, pressing may be carried out overall with less total force.

In an advantageous configuration of the invention, an aforementioned protruding section of the rib may form a substantial region thereof. This protruding section is advantageously arranged above the operating element housing, so that it can be moved more freely, or more freely bent away or around. A further region of the rib may directly extend along on the upper side or on an outer side of the operating element housing for fastening thereof, and under certain circumstances may also extend therein for reliable and permanent fastening.

In another configuration of the invention, the protruding section of the rib may stand outward from an upper side or an upper region of the operating element housing, i.e. it is substantially distant from a surface at least approximately defined by the ribs of an operating element housing. In this way, for example, a light provided inside the operating element housing may remain unaffected, or have substantially the area of the upper side of the operating element housing available.

An angle, with which the section or the essential part of the rib protrudes laterally, may advantageously be from 30° to 60°. Particularly advantageously, it is between 40° and 50°. The shallower the angle is, the more easily the protruding section can be pressed down, or the more elastic is the rib substantially against pressure force from above. At the same time, naturally, the available spring distance decreases, so that a compromise is to be found.

In one basic configuration of the invention, the rib, or its cross section, may be formed solidly without cavities. This applies in particular for the protruding section, or the region of the rib over or outside the operating element housing. The elasticity is then essentially achieved by the oblique setting, or protruding shape, of the protruding section. Under certain circumstances, the protruding section, in particular close to the operating element housing or in a transition therewith, may have an incision or the like. This may have a substantial hinge effect for easier tilting.

In an alternative basic configuration of the invention, the rib or its cross section may also be made particularly elastic by providing an undercut opening, or by the rib being a hollow profile. Thus, elasticity can be further increased even with small undercuts. By means of a hollow profile, a relatively large outer surface can be achieved with a small wall thickness and therefore low strength. Here again, geometrical elasticity is substantially achieved.

In yet another configuration of the invention, the at least one rib is elongate and as seen in longitudinal cross section is bent convexly away from the upper side of the operating element housing. This means that as seen in longitudinal cross section the rib first extends away somewhat to the side from the operating element housing and is then bent upward. An end direction of the bending on a free edge of the rib, i.e. the end of the longitudinal cross section, may be or extend at an angle of from 60° to 90° with respect to the upper side. With this configuration of the rib, when pressing on an operating panel or cover thereover, the rib can be pressed away downward even more easily than only by lateral protrusion, so that the required application force or spring force is further reduced.

In one configuration of the invention, it is possible respectively to provide a protruding rib with an aforementioned bend in longitudinal cross section only on two of four longitudinal sides of the operating element housing. Advantageously, they are provided on opposite longitudinal sides, particularly advantageously on opposite shorter longitudinal sides. On the other longitudinal sides, either normally continuous ribs or rib sections may be provided or the aforementioned plurality of rib sections with interruptions along a longitudinal side. Furthermore, it is even possible that on a longitudinal side with such a rib bent as seen in cross section, which stands somewhat laterally from the operating element housing, upwardly protruding ribs or rib sections may be provided on top of the operating element housing.

In another configuration of the invention, it is possible that, although the rib is also elongate, it is bent in its longitudinal extent, irrespective of the nature of its longitudinal cross section. This bending, of the rib in the longitudinal extent begins on a rib base on the operating element housing, so that the rib firstly extends obliquely upward, or in a direction upward with respect to the operating panel. It then extends beyond the upper side of the operating element housing with a bending angle becoming increasingly shallower. The rib then reaches a high point and passes through this in its longitudinal extent, then is bent downward again. Advantageously, the bending is approximately symmetrical in the rising and falling regions. At the other end, the rib may either be connected again to the operating element housing, particularly on a corner of the operating element housing or a corner region, or alternatively the other end of the rib may be a free end without fastening on the operating element housing. An application force can also be reduced greatly by such bending of the rib, namely in the longitudinal extent. This depends above all on the fact that, in the case of rather shallow bends of the rib, it is only necessary to bend very little or press down per unit length in relation to the distance by which it must be bent downward overall.

While the configurations described above are based on a rib extending along a longitudinal side of the operating element housing and being connected to the operating element housing or fastened thereon at least in the corner regions, in a further configuration of the invention a rib may be bent differently from a straight line, or be U-shaped, in its longitudinal extent in plan view of the operating element housing, or the upper side thereof. In this case, it is thus possible for a rib to extend not from corner to corner but from a point on a longitudinal side of the operating element housing which is somewhat away from a corner, and over this corner and advantageously also over the next corner, again to a point which lies somewhat beyond a corner in the longitudinal side of the operating element housing. Above all in an above-described embodiment of a rib with bending in the longitudinal extent, this is advantageous since the rib can be bent upward in this angled or U-shaped longitudinal extent. Thus, its length comprising the bend is further increased and an application force necessary for pressing is further reduced. The rib may in this case be connected at both ends to the operating element housing, or fastened thereon. Furthermore, such an angularly extending or U-shaped rib may extend within the contour of the operating element housing in plan view of the upper side, that is to say it does not project laterally. The maximum height of the bending of a rib bent in the longitudinal extent over the operating element housing, or over the upper side, may be a few millimeters, advantageously from 0.5 mm to 2 mm or 3 mm, or may be about 50% to 200% of the height of the rib itself

Advantageously, the operating element housing is substantially formed rectangularly in plan view, particularly advantageously overall in the shape of a block. A rib should extend on at least two of its sides, advantageously on neighboring sides. Particularly advantageously, a rib extends on all four sides or side regions of the operating element housing. A plurality of ribs are generally advantageously formed in the same way, or with the same cross section.

In the configuration described above of a plurality of ribs along the side regions of the operating element housing, a protruding section should not be provided in corner regions. The high elasticity can be preserved by this interruption in the corner regions. Equally, the rib may advantageously also extend over the corner regions, in particular with a flat base region, in order to connect together protruding sections on different sides of the operating element housing. In this way, it is possible to achieve one-piece production, which on the one hand is simpler. On the other hand, a continuous electrical conductivity can be achieved for the aforementioned properties as a capacitive sensor element. Such continuous connecting sections of the ribs may then extend as a base or base region directly on the operating element housing, or therein.

A height of a protruding section may lie between 0.5 mm and 3 mm, for example from 5% to 20% of the height of the operating element housing. A height of about 0.8 to 1.5 mm with an operating element housing height of between 3 mm and 8 mm is generally regarded as advantageous. A thickness of such a protruding section may be somewhat less than its height, for example about half the height.

For aforementioned properties of the rib or the protruding sections as a capacitive sensor element, its elastic material should be electrically conductive. It may generally be an elastomer or a thermoplastic elastomer (TPE), likewise rubber. It may be made electrically conductive by additives from the group carbon black, graphite, metal powder and/or carbon nanotubes, above all in the case of TPE. Here, costs and sufficient electrical conductivity should be taken into account.

These and other features may furthermore be found in the claims and the description and the drawings. The individual features may be implemented individually or several together in the form of subcombinations in an embodiment of the invention and in other fields, and may represent advantageous and protectable embodiments for which protection is claimed here. The division of the application into subheadings and individual sections does not restrict the comments made therein in their general applicability.

### BRIEF DESCRIPTION OF THE SEVERAL VIEWS OF THE DRAWINGS

Exemplary embodiments of the invention are schematically represented in the drawings and will be explained in more detail below. In the drawings:

FIG. 1 shows a lateral section through an operating element according to a first aspect of the invention,

FIG. 2 shows a side view through an installed state of the operating element of FIG. 1 in an operating device,

FIGS. 3 to 6 show different variants of an operating element of the invention in a similar way to FIG. 1 with differently formed ribs on the upper side, and

FIGS. 7A, 7B, 8A, 8B, 9A, 9B, 10A, 10B, 11A, 11B, 11C, and 12 to 15 show further different variants of an operating element of the invention with differently formed ribs on the upper side.

### DETAILED DESCRIPTION

FIG. 1 represents an operating element 11 according to the invention having an operating element housing 13, which consists of a shell body 14 with holding feet 15 on the lower side and a light guide 17 therein, as well as a central recess 18. Such an operating element 11 is known in principle from the aforementioned WO 2013/174728 A1, to which reference is expressly made in this regard. Instead of the light guide, a disc or sheet could be provided for scattering or light distribution, respectively.

Above on the operating element housing, 13, or on the upper side, or on an outer edge, ribs 20a to 20c are fitted, preferably by multicomponent injection moulding onto the operating element housing, 13, or the shell body 14. While the shell body 14 consists of light-nontransmissive plastic and the light guide 17 consists of light-transmissive plastic, the ribs 20a to 20c consist of an elastomer, advantageously an aforementioned electrically conductive elastomer, for example TPE. The inherent hardness of the elastomer may be about 10 to 70 Shore A, advantageously from 20 to 60 Shore A, so that it is relatively soft and elastic.

The cross sections of the ribs 20 are respectively the same. For example, the rib 20a has a lower base region 21a, which is arranged directly on the operating element housing 13, or the shell body 14. The base region 21a merges into a protruding region 23a, here in the manner of an obliquely standing lip or the like. The cross sections of the ribs 20a to 20c are respectively the same over their lengths. The base region 21a to 21c may also be sunk or injected somewhat into the operating element housing 13, or the shell body 14, and/or light guide 17 for better fastening. A further fourth rib corresponding to the rib 21d is provided, but is not represented here.

From the right-hand rib 20c, or from the base region 21c, web-like contacting 20 on the outer region of the shell body 14 extends downward and opens into a contact region 27′. The latter is used for electrical contacting of the ribs 20a to 20c, as will be explained in more detail below.

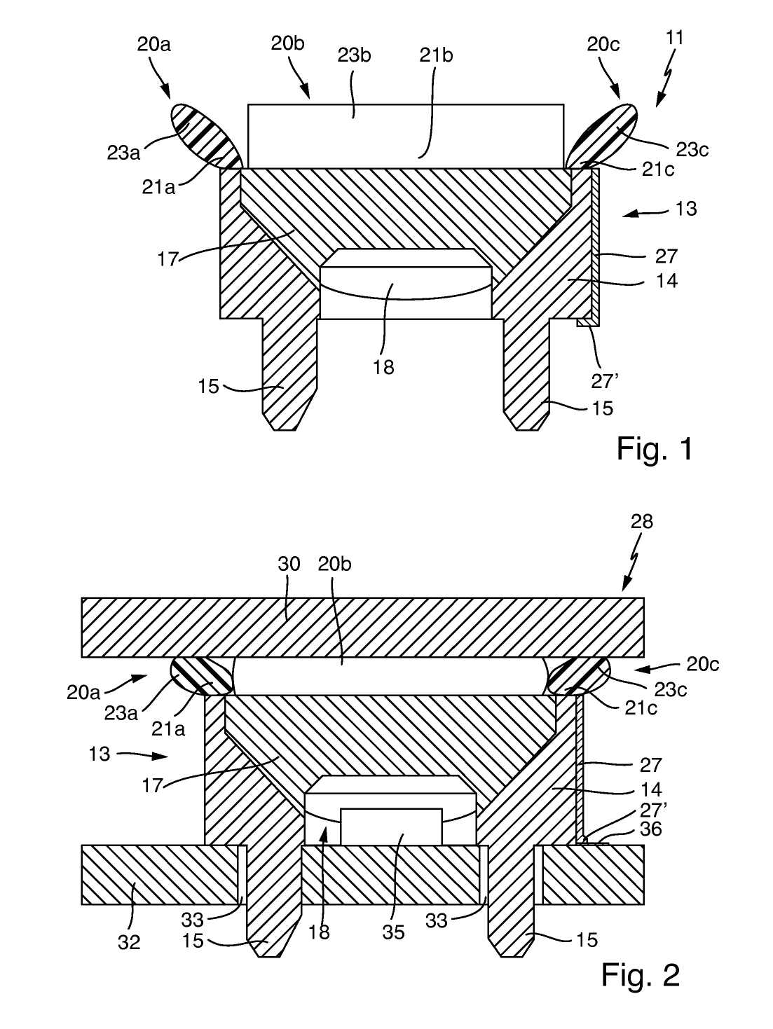

The installed state of the operating element 11 is shown by FIG. 2 by means of an operating device 28 together with an operating surface 30 in the form of a thin and at least partially light-transmissive plate. The operating element 11 is pressed onto a lower side of the operating surface 30 with a certain force. The operating surface 30 thus presses the ribs 20a to 20c downward somewhat. Their height is only about two thirds compared with that in FIG. 1. Owing to the formation of the obliquely protruding sections 23a to 23c, the deformation of the ribs 20a to 20c takes place essentially by bending the sections 23a to 23c downward. In the prior art mentioned in the introduction in the form of WO 2013/174728 A1, this was not possible, and the ribs 20a to 20c could only be elastically compressed. It is clear that the shape given here by the protruding sections 23a to 23c allows bending or pressing downward with significantly less force than compression. Owing to the protruding profile of the protruding sections 23a to 23c with an angle of about 45°, and as seen over their imaginary longitudinal mid-axis, with respect to the plane of the upper side of the operating element housing 13 or of the shell body 14, they are already preset obliquely in such a way that they can be bent away or around slightly more when pressing down onto the lower side of the operating surface 30.

Furthermore, the operating device 28 has a printed circuit board 32 with holes 33, into which the holding feet 15 are retainingly inserted. An LED 35, which protrudes into the recess 18 and shines through the light guide 17 for lighting which can be seen from above through the light-transmissive operating surface 30, is arranged on top of the printed circuit board 32. Toward the side, the light is shielded by the shell body 14, which is seated firmly on the upper side of the printed circuit board 32, as well as the ribs 20a to 20c, or all four ribs provided around. Here, it can also be seen that the contact foot 27′ of the contacting 27 is pressed onto a contact area 36 on the printed circuit board 32 for electrical contacting by means of conductor tracks (not represented) on the ribs 20. The ribs 20, or their elongate regions pressed onto the lower side of the operating surface 30, form a capacitive operating element, or a capacitive sensor surface, as described in WO 2013/174728 A1, which was mentioned in the introduction.

From the representation of FIGS. 1 and 2, it is also relatively clear why the ribs 20a to 20c should not be connected continuously to one another in the corner regions of the operating element housing 13, at least not above on the protruding sections 23a to 23c. Otherwise, they can only be bent around and outward much less well, since this would otherwise involve an extension of their circumferential length, and this is only possible with difficulty in the case of a closed circumferential design. Instead, for example, the base regions 21a to 21c may be formed circumferentially, each with individually placed sections 23 protruding outward.

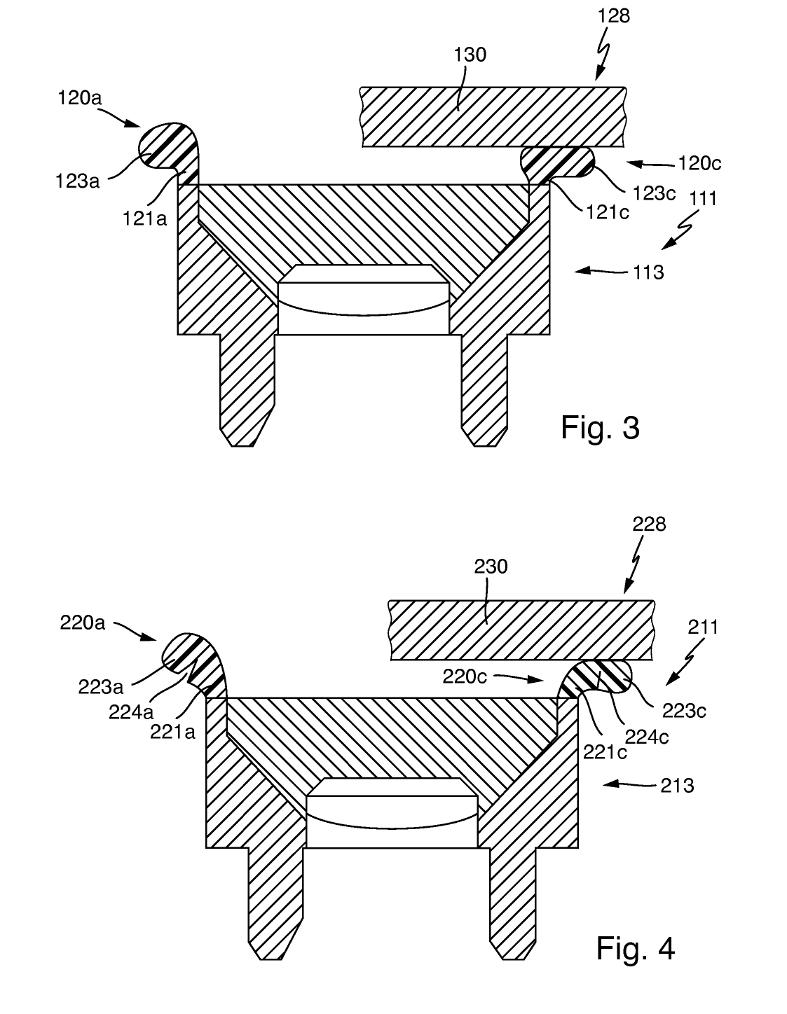

In a variant of an operating element 111 according to FIG. 3, a rib 120a whose cross section is formed approximately squarely, or rectangularly, is represented on the left. A rounded protruding section 123a extends from a base region 121a that extends upward from the operating element housing 113.

The installed state, that is to say when the operating element 111 is pressed against the lower side of an operating surface 130, i.e. in a similar way as in FIG. 2, is represented on the right in FIG. 3. Here, it can be seen that the protruding section 123c is then pressed downward and therefore essentially follows a bending deformation of the rib 120c. Beyond a certain distance of the pressing together, at least the base region 123c can only be compressed, so that the spring force or resistance of the rib 120c against pressing together increases significantly.

FIG. 4 represents another operating element 211. A rib 220a represented in the relaxed state on the left has a base region 221a and a protruding section 223a following on therefrom. An incision 224, which is clearly used for easier bending of the protruding section 223a downward, is provided between them. This can be seen in FIG. 4 from the right-hand side, when the operating element 211 is pressed onto the lower side of an operating surface 230. Then, the protruding section 223c is bent downward so far that it bears fully on the base region 221c and the incision 224 is therefore substantially closed. Beyond this, as described above similarly for FIG. 3, the resistance of the rib 220c against further pressing together increases greatly.

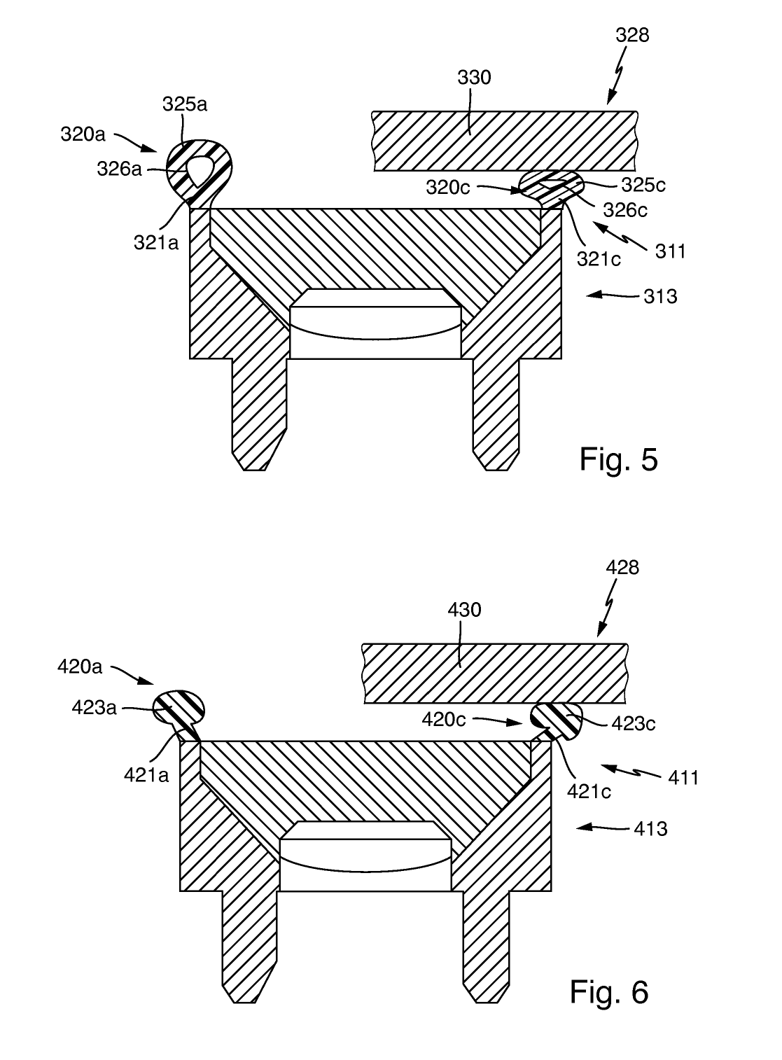

FIG. 5 represents another operating element 311, which has a rib 320a in the left-hand region on top of the operating element housing 313. Over a base region 321a, this rib 320a has an annular region 325a with a cavity 326a. By virtue of such a cavity 326c, as can be seen clearly on the right in FIG. 5, a rib 320c can be pressed together easily when pressing onto the lower side of an operating surface 330. Here again, the pressing together or deformation of the rib 320c can take place relatively easily until the cavity 326c has so to speak vanished. Beyond this point, the rib 320c can only be squeezed together with elastic compression of the material.

Yet another configuration is represented in FIG. 6. There, in the left-hand region, an operating element 411 has a rib 420a with a base region 421a which protrudes somewhat over the operating element housing 413 and stands slightly outward. The base region 421a carries an outwardly protruding section 423a significantly larger in proportion thereto, so that the base region 421a is thin in comparison therewith.

On the right, it can be seen from FIG. 6 that pressing onto the lower side of an operating surface 430 bends the base region 421c, while the protruding section 423c is pressed together, or pressed flat, only slightly on its upper side. Here, the easy geometrical deformability of the ribs 420a and 420c results primarily from the configuration of the base region 421a and 421c. The advantage in this configuration of the invention is that the contact surface being formed above on the rib 420a and 420c, or on the protruding section 423a and 423c, remains approximately the same over a larger range of the pressing of the ribs 420a and 420c onto the lower side of the operating surface 430. This is achieved by essentially only the base region 421a and 421c being bent off, or bent downward.

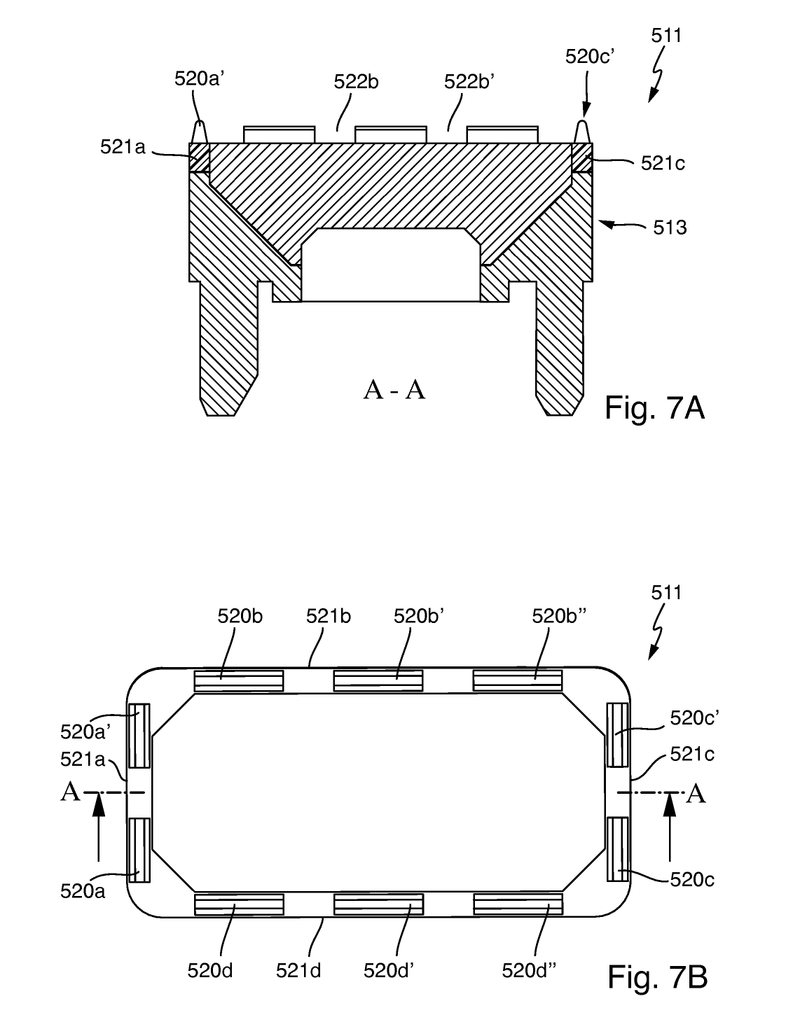

Another operating element 511 according to the first basic aspect of the invention as mentioned in the introduction is represented in FIG. 7A in side view and 7B in plan view thereof, which corresponds essentially to the previous one and will only be explained in detail with respect to its differences. The operating element 511 has an operating element housing 513 with ribs on the upper side or on an outer edge of the operating element housing, or rib sections 520a and 520a′ on the left-hand side, 520b, 520b′ and 520b″ on the rear longitudinal side and rib sections 520d, 520d′ and 520d″ on the front longitudinal side, as well as rib sections 520c and 520′ on the right-hand or short right-hand longitudinal side. According to FIG. 7A, the ribs have a rib base 521 a on the left and a rib base 521c on the right, which is represented here in section. Not only are these ribs therefore injection-moulded or inserted directly above onto the operating element housing 513 or a respective plastic, but for increased stability the rib bases 521a to 521d are also injection-moulded into a corresponding angled section. From these, the individual rib sections 520 extend upward.

It can be seen clearly both from the side and from the top that, compared for example with FIG. 1, no rib extending over the essential part of the length of a side of the operating element housing 513 is provided. Here, the individual rib sections 520b, 520b′ and 520b″ are provided by the interruptions 522b and 522b′ which can be seen in FIG. 7A. It can be seen from the cross section that the rib sections 520 are tapered upward, or away from the upper side, and have a rounded region at the end. Although on the one hand this leads to a relatively narrow bearing surface on the lower side of an operating device, or its operating surface, for example according to FIG. 2, this is nevertheless sufficient for the function as a capacitive sensor element or capacitive touch sensor. Owing to the ratio of the total length of the interruptions 522b and 522b′ on the one hand and the rib sections 520b, 520b′ and 520b″ on the other hand, however, a reduction in the application force is achieved. Here, an interruption 522 is just under half as long as a rib section 520, so that the necessary application force is reduced by a quarter to a third.

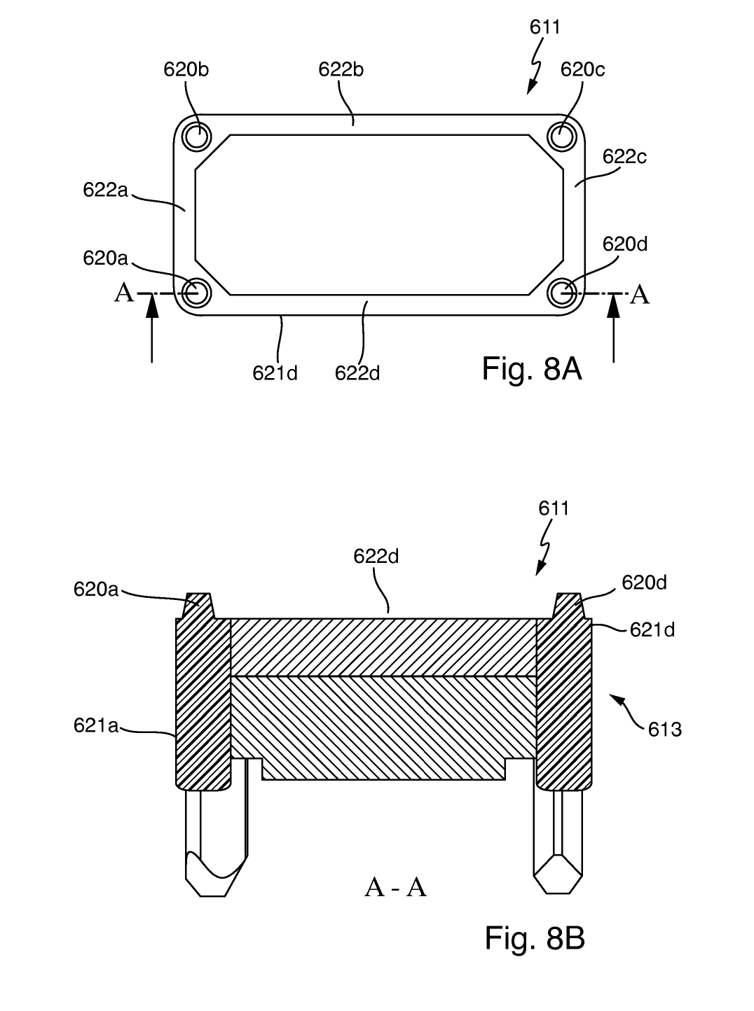

An exemplary embodiment of a configuration, likewise described in the introduction, of an operating element 611 is represented in FIG. 8A in plan view and 8B in section along A-A, in which rib sections 620a to 620d are greatly shortened substantially so that, so to speak, they are as long as they are wide and only form a kind of post. These post-like rib sections 620a to 620d are provided here in corner regions on the upper side of the operating element housing 613, or injection-moulded from above onto rib bases 621a and 621d according to FIG. 8B, these rib bases here extending as far as the lower side and, in particular, being used for electrical contacting below in a similar way to the contacting 27 or the contacting region 27′ of FIG. 1. The post-like rib sections 620a to 620d could also respectively be seated approximately in the middle of a longitudinal side of the operating element 611. Furthermore, more of them could also optionally be provided. In any event, it can be seen here that the round and frustoconical, or rotationally symmetrical, rib sections 620a to 620d form extremely shortened rib sections with very long interruptions 622a to 622d compared with FIGS. 7A and 7B, which at the same time leads to a greatly reduced application force. In tests, however, it has been found that this is sufficient for the function as a capacitive sensor element, or as a capacitive touch switch. By virtue of the tapering of the post-like rib sections 620a to 620d, on the one hand a further slight reduction in the application force can be achieved, and on the other hand easier production is achieved.

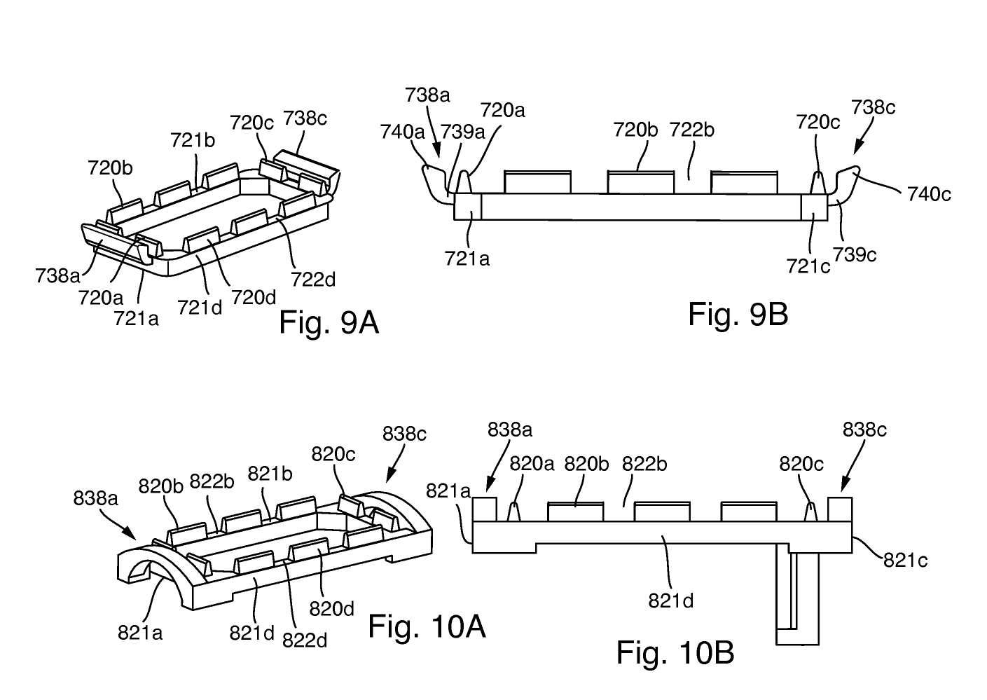

FIGS. 9A and 9B, as well as the further figures, no longer represent an entire operating element, but so to speak only in a similar way to FIG. 7A a circumferential rib base 721 with ribs or rib sections 720 provided on the upper side. This rib base 721 may, as previously described, be formed on an operating element housing, not all of which is represented here for simplicity.

On the one hand, in FIG. 9A in oblique plan view and 9B in side view, it can be seen that, according to FIGS. 7A and 7B, individual rib sections 720 are provided, which are not mentioned in detail since to this extent they correspond to the aforementioned FIGS. 7A and 7B. In the region of the rib bases 721a and 721c, however, additional ribs 738a and 738c are also provided in addition to the rib sections 720. In a substantially similar way as in the exemplary embodiments of FIGS. 3 and 4, these have a bend in cross section, but precisely the other way round than in the aforementioned FIGS. 3 and 4. From the rib bases 721, a rib base 739a and 793c, respectively, firstly extends away to the side, or outward. The rib is then respectively bent upward and opens into an end region 740a and 740c, respectively. This then stands essentially upward, or at an angle with respect to an operating surface or an upper side of an entire operating element body, which is pressed from above, of about 75° to 90°. By the slight widening of the ribs toward the free end, or toward the end section 740a or 740c, wider bearing on the lower side of the operating surface, or a somewhat enlarged bearing surface, is achieved. In a similar way as in the exemplary embodiment of FIGS. 3 and 4, the elasticity or easy flexibility downward is achieved here above all by the configuration or shaping, namely by the angling off

In this exemplary embodiment, it can thus be seen that substantially both types of ribs, on the one hand with interruptions and on the other hand with a design protruding at an angle, may be provided together on an operating element. It is, however, obviously to be understood that either only the two angled-off ribs 738a and 738c may advantageously be provided, that is to say no rib sections 720 with interruptions between them, or these may also be provided with angled-off ribs 738 along the long longitudinal sides of an operating element housing.

Yet another configuration of ribs or rib sections for an operating element is represented in FIG. 10A in oblique view and 10B in side view. This configuration as well, in a similar way to that of FIGS. 9A and 9B, derives from FIG. 7A with the rib bases 821a to 821d and the rib sections 820 seated thereon. Here, however, unlike in FIGS. 9A and 9B, ribs bent or angled-off in longitudinal cross section are not provided on the rib bases 821a and 821c, but instead ribs 838a and 838c curved in a bridge-like fashion in longitudinal cross section. They extend over the entire width of the short longitudinal sides or the rib bases 821a and 821c. They are curved in approximately the same way on an upper side and project somewhat beyond the upper edges of the rib sections 820. With an operating element housing length of about 10 mm, the rib sections may be about 0.6 mm high, while the ribs 838a and 838c, in a similar way as the ribs 738a and 738c, extend about 1 mm upward, i.e. extend beyond the respective rib sections by about 0.4 mm.

From FIG. 10A, it is clear that the shape of the ribs 838a and 838c bent upward in longitudinal extent, starting from a base on the rib bases 821a or 821c, gives a very elastic configuration, i.e. a low application force onto a lower side of an operating surface is to be expected. In such a bearing, although the rib 838 does not bear on the lower side of the operating surface with its entire length, but probably with about 30% to 60%, this has proven sufficient in tests for the function as a capacitive sensor element of a touch switch.

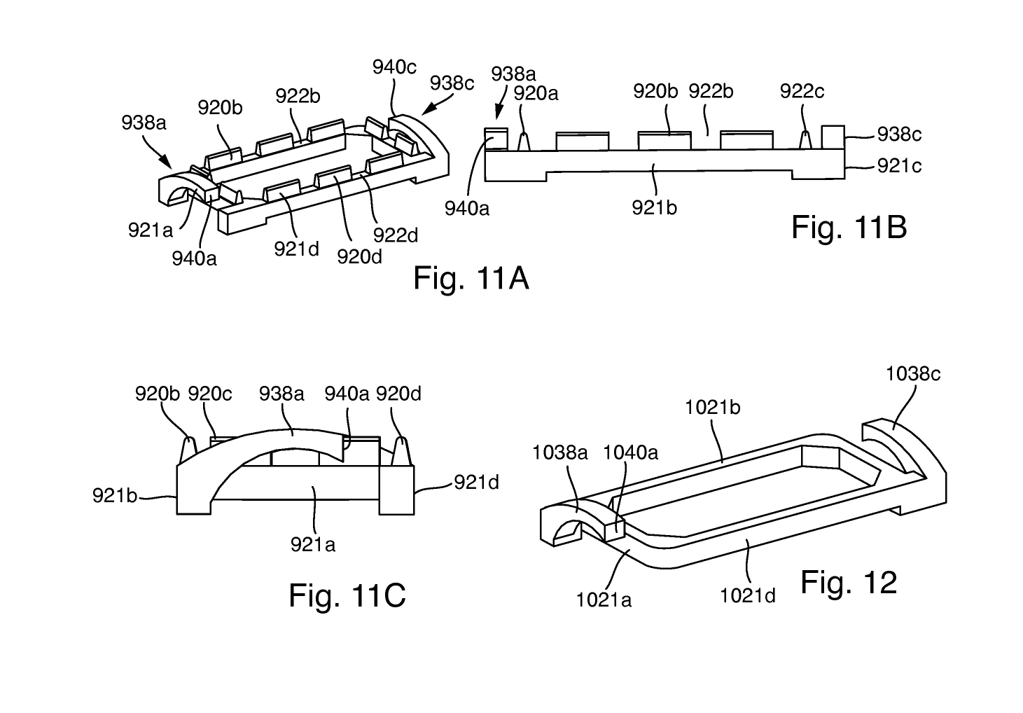

A variant of the configuration of FIGS. 10A and 10B is shown in FIGS. 11A to 11C. Here, rib bases 921a to 921d are also represented, which carry rib sections 920 with interruptions between them. On the rib bases 921a and 921c, in the longitudinal extent, ribs 938a and 938c are provided. Unlike in the configuration of FIGS. 10A and 10B, however, these are not continuous, or connected at both ends to a rib base 921, but only at one end. The other end of the ribs 938 is free as a free end 940a and 940c, respectively. In this way, the flexibility of the ribs 938 can clearly be further increased significantly, or an application force resulting therefrom onto the lower side of an operating surface becomes much less, since it is predictably very easy to bend the rib 938 downward somewhat. The area or size of the region bearing on the operating surface should probably be similar as in the embodiment of FIGS. 10A and 10B. Likewise, the ribs 938 rise similarly high at their highest point as in the exemplary embodiment of FIGS. 10A and 10B.

FIG. 12 represents yet another embodiment of the invention, which is derived from the exemplary embodiment of FIGS. 11A to 11C, or has the same rib bases 1021a to 1021d and the same ribs 1038a and 1038b, identically as in the aforementioned exemplary embodiment. Here, however, no rib sections are provided on the upper sides of the rib bases 1021a to 1021d, so that the capacitive sensor element bears on the lower side of an operating surface only with the upper sides of the ribs 1038a and 1038b, for the action of a capacitive touch switch. This, however, has also been found to be sufficient. By omitting the rib sections, the full height of the extent of the ribs 1038 above the upper side of the rib bases 1021 is achieved as a possible spring distance. Since the ribs 1038 are arranged on protuberances or projections which protrude from the rib bases 1021a and 1021c, the ribs themselves can still be pressed downward at their base on these projections with a sufficient application force, so that the upper side of the rib bases 1021 can actually be pressed onto the lower side of an operating surface, if necessary.

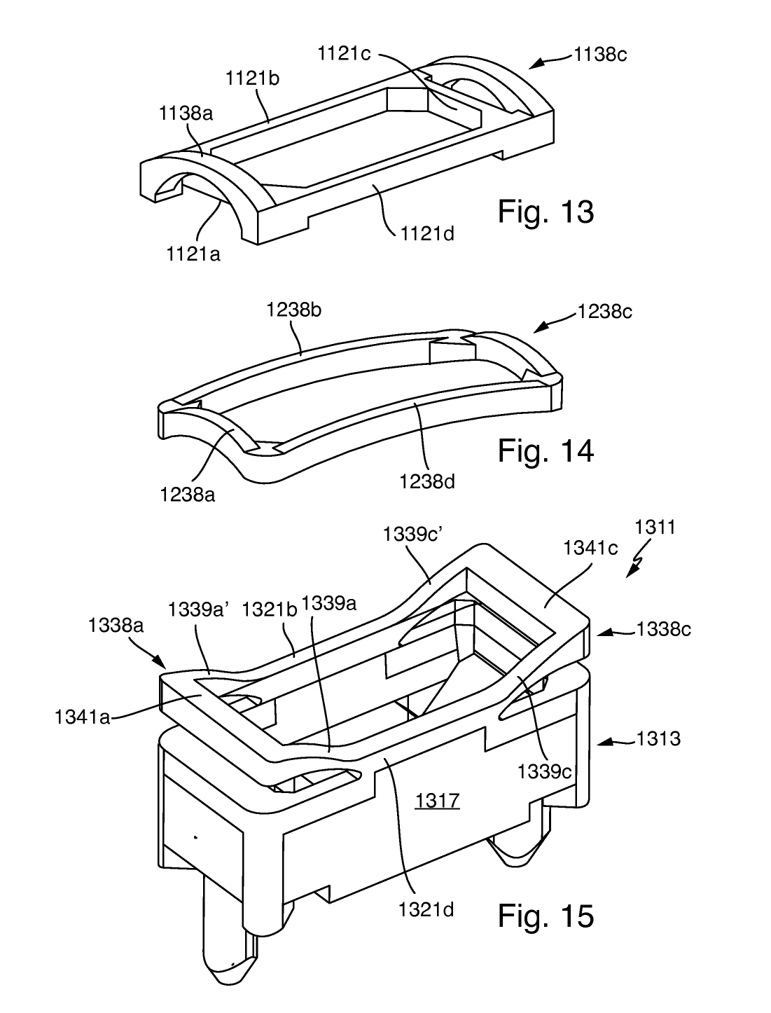

Yet another configuration, derived from FIG. 12, is represented in FIG. 13, which corresponds in principle to the configuration of FIGS. 10A and 10B but without rib sections on the upper sides of the rib bases 1121a to 1121d. Here, arc-like ribs 1138a and 1138c are likewise provided on the short rib bases 1121a and 1121c, or on projections again standing forward. These are formed in the same way as in FIGS. 10A and 10B, to which reference is made. The same advantages can be achieved by them as mentioned there.

FIG. 14 represents yet another configuration, in which, so to speak, all the rib bases are formed as curved ribs 1238a to 1238d standing up. The difference is that in the corner regions, in which the ribs 1238a to 1238d are connected to one another, they are also connected to an operating element housing or shell body, in particular injection-moulded thereon. With this configuration, the application force is substantially increased somewhat from that of FIG. 13, since now actually all four arc-shaped ribs 1238a to 1238d can and should bear on the lower side of an operating surface. Yet since, owing to the arc-shaped configuration, there is a very small application force anyway, this should not be a problem. Furthermore, the bearing surface is significantly increased, or at least doubled.

Somewhat more complex is the exemplary embodiment of FIG. 15 with an operating element 1311 together with an operating element housing 1313, in which a complex structure of correspondingly elastic and electrically conductive plastic is provided, or injection-moulded, on the upper side. On the one hand, although, similarly as before, such plastic can be injection-moulded circumferentially or in the manner of a frame onto the upper side of a light guide 1317 with two rib bases 1321b and 1321d along the long longitudinal sides of the operating element 1311, ribs 1338a and 1338c standing up in longitudinal extent are also provided, these respectively protruding not from the corner regions between the rib bases, but rather being connected toward the middle with the rib bases 1321b and 1321d. Rib bases 1339a and 1339a′, or respectively 1339c and 1339c′, protrude from the rib bases 1321b and 1321d with bending obliquely upward in the direction toward the short longitudinal sides of the operating element housing 1313. Above the short longitudinal sides, they merge into a respective transversely extending transverse region 1341a and 1341c, and the upper sides of these transverse regions 1341a and 1341c then bear on the lower side of an operating surface. As can readily be seen, the spring action achieved by the shaping is achieved by a kind of hinge function on the base 1339, which are also clearly formed to be very thin. Furthermore, the longitudinal regions between the transverse regions 1341 and the base regions 1339 may also be bent downward for flexibility, or resilient configuration.

With this configuration, it is likewise possible to achieve a very small application force, but with a much larger application surface, namely that of essentially the entire upper side of the transverse regions 1341. For yet further reduction of a necessary application force, the transverse regions 1341 could also be bent upward according to the configuration of FIGS. 10A and 10B.

1. An operating element having an operating element housing, wherein in an upper region or on an upper side of said operating element housing at least one protruding rib made of elastic material extending at least partially along is arranged, wherein in a longitudinal extent of said rib an interruption is provided in said longitudinal extent to subdivide said rib into at least two protruding rib sections.

2. The operating element according to claim 1, wherein said operating element housing is formed rectangularly in plain view, with ribs along each side, said ribs along each side being subdivided into at least two rib sections by said interruptions.

3. The operating element according to claim 2, wherein a sum of said lengths of said interruptions along a side is less than a sum of said lengths of said individual rib sections.

4. The operating element according to claim 3, wherein said sum of said lengths of said interruptions along a side is less than 20% to 60% of said sum of said lengths of said individual rib sections.

5. The operating element according to claim 1, wherein a sum of said lengths of said interruptions in said rib is greater than a sum of said lengths of said rib sections themselves.

6. The operating element according to claim 5, wherein said sum of said lengths of said interruptions in said rib is from 5 times to 20 times as great as said sum of said lengths of said rib sections.

7. The operating element according to claim 5, wherein said operating element housing is polygonal in plan view, rib sections being provided only in corner regions of said operating element housing.

8. The operating element according to claim 7, wherein one of said rib sections with a length which corresponds approximately to its width is provided in each said corner region of said operating element housing.

9. The operating element according to claim 1, wherein a width of said ribs is between 50% and 150% of a height of said ribs.

10. The operating element according to claim 9, wherein said width of said ribs at a base on said operating element housing or its upper side is between 50% and 150% of said height of said ribs.

11. The operating element having an operating element housing, in an upper region or on an upper side of said operating element housing a protruding rib made of elastic material extending at least partially along is arranged, wherein said rib or its cross section is formed for geometrical elasticity by an elastically protruding section with an extent direction away from a rest of said rib, essentially obliquely with respect to a plane of said upper side of said operating element.

12. The operating element according to claim 11, wherein said protruding section forms said substantial region of said rib above said operating element housing.

13. The operating element according to claim 11, wherein said protruding section stands outward from an upper side of said operating element housing.

14. The operating element according to claim 13, wherein said protruding section projects laterally outward beyond said operating element housing.

15. The operating element according to claim 11, wherein said protruding section has an angle of between 30° and 60° with respect to a plane of said upper side of said operating element.

16. The operating element according to claim 11, wherein said rib, or its cross section, is solid without cavities, particularly in a region over said upper side of said operating element housing.

17. The operating element according to claim 16, wherein said rib, or its cross section, is solid without cavities in a region over said upper side of said operating element housing.

18. The operating element according to claim 11, wherein said rib or its cross section has an undercut opening or is hollow.

19. The operating element according to claim 18, wherein said rib or its cross section has an undercut opening or is hollow in the manner of a hinge.

20. The operating element according to claim 11, wherein said rib is elongate and as seen in longitudinal cross section is bent convexly away from said upper side of said operating element housing.

21. The operating element according to claim 20, wherein an end direction of said bending on a free edge of said rib is at an angle of from 60° to 90° with respect to said upper side.

22. The operating element according to claim 20, wherein one protruding rib with bending in longitudinal cross section is provided only on two of four said longitudinal sides of said operating element housing.

23. The operating element according to claim 11, wherein said rib is elongate and is bent in its longitudinal extent starting from a base on said operating element housing, firstly over said upper side of said operating element housing with a bending angle becoming shallower.

24. The operating element according to claim 23, wherein said rib is bent back down again in its longitudinal extent after reaching a high point, and is connected to said operating element housing at said other end, or said other end is a free end without fastening.

25. The operating element according to claim 23, wherein said extent of a rib with bending in its longitudinal extent, in plan view of said operating element housing, is bent differently from a straight line, or is U-shaped.

26. The operating element according to claim 25, wherein said rib is connected to said operating element housing or fastened thereon, at both ends and extends inside said contour of said operating element housing in plan view of said upper side.

27. The operating element according to claim 11, wherein said operating element housing is formed substantially rectangularly and ribs extend on its sides, one said rib being arranged on each of said four sides of said operating element housing.

28. The operating element according to claim 27, wherein no protruding section is provided in corner regions of said operating element housing, wherein said rib extends over said corner regions to connect protruding sections of different sides of said operating element housing to one another without protruding sections on said corner regions.

29. The operating element according to claim 11, wherein a height of one said protruding section is from 0.5 mm 3 mm.

30. The operating element according to claim 11, wherein said elastic material is electrically conductive TPE, additives for said electrical conductivity being selected from the following group: carbon black, graphite, metal powder, carbon nanotubes.
